(19) United States
(12) Patent Application Publication
(10) Pub. No.: US 2026/0113881 A1
(43) Pub. Date: Apr. 23, 2026

(54) COOLING DISTRIBUTION UNIT

(71) Applicant: LTI Holdings, Inc., Pleasanton, CA (US)

(72) Inventor: Peter D. Bennett, Hampton, NH (US)

(21) Appl. No.: 19/359,968

(22) Filed: Oct. 16, 2025

Related U.S. Application Data
(60) Provisional application No. 63/709,129, filed on Oct. 18, 2024.

(51) Int. Cl. H05K 7/20

(52) U.S. Cl. CPC H05K 7/20281; H05K 7/20272

(57) ABSTRACT

A cooling distribution unit includes an electronic processor. The electronic processor is configured to determine whether both a temperature sensor associated with an inlet of a secondary closed loop and a temperature sensor associated with an outlet of the secondary closed loop have failed. The electronic processor is configured to, in response to determining that the temperature sensors have failed, determine whether the CDU is in single mode or group mode. The electronic processor is also configured to, in response to determining the CDU is in single mode, determine a temperature differential between a first temperature received from a temperature sensor associated with an inlet of a primary closed loop and a second temperature received from a temperature sensor associated with an outlet of the primary closed loop and control a pressure independent control valve based on the determined temperature differential.

### CROSS-REFERENCE TO RELATED APPLICATIONS

This application claims priority to U.S. Provisional Application No. 63/709,129, filed October 18, 2024, the entire contents of which are incorporated herein by reference.

### FIELD

The present disclosure generally relates to cooling distribution units for directing heat away from electrical components.

### BACKGROUND

Cooling distribution units (commonly referred to as CDU’s) are often utilized in data centers to remove heat from computer components (e.g., servers and server racks). CDUs may include, for example, both in-row units and in-rack units. In-row units remove heat from an entire row of server racks or other sets of electrical components, while in-rack units typically remove heat from a single rack or set of electrical components.

### SUMMARY

In accordance with one example, a CDU includes a primary closed loop, wherein a first fluid circulates through the primary closed loop, a secondary closed loop, wherein a second fluid circulates through the secondary closed loop, a pressure independent control valve, a first temperature sensor associated with an inlet of the primary closed loop, a second temperature sensor associated with an outlet of the primary closed loop, a third temperature sensor associated with an inlet of the secondary closed loop, a fourth temperature sensor associated with an outlet of the secondary closed loop, and an electronic processor. The electronic processor is configured to determine whether both the third temperature sensor and the fourth temperature sensor have failed. The electronic processor is configured to, in response to determining that both the third temperature sensor and the fourth temperature sensor have failed, determine whether the CDU is in a single mode or a group mode. The electronic processor is also configured to, in response to determining the CDU is in the single mode, determine a temperature differential between a first temperature received from the first temperature sensor and a second temperature received from the second temperature sensor and control the pressure independent control valve based on the determined temperature differential.

In accordance with another example, a CDU includes a secondary closed loop, wherein a second fluid circulates through the secondary closed loop, a dew point temperature sensor, a pressure independent control valve, and an electronic processor. The electronic processor is configured to receive a temperature of the second fluid determined by a temperature sensor associated with an outlet of the secondary closed loop, receive a temperature threshold, and receive a dew point temperature from the dew point temperature sensor. The electronic processor is also configured to determine whether the dew point temperature is outside a normal range and determine whether the dew point temperature sensor is disconnected. The electronic processor is also configured to, in response to determining the dew point temperature from the dew point temperature sensor is outside of the normal range or the dew point temperature sensor is disconnected, determine whether the CDU is in a single mode or a group mode. The electronic processor is further configured to, in response to determining the CDU is in the single mode, determine a dew point temperature threshold, wherein the dew point temperature threshold is the received temperature threshold and determine whether the determined temperature of the second fluid is below the dew point temperature threshold. The electronic processor is also configured to, in response to determining the determined temperature of the second fluid is below the temperature threshold, control the pressure independent control valve to increase temperature of the second fluid.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a CDU in accordance with one example.

FIG. 2 is a perspective view of the CDU of FIG. 1.

FIG. 3 is another perspective view of the CDU of FIG. 1.

FIG. 4 is another perspective view of the CDU of FIG. 1

FIG. 5 is a block diagram of a controller in accordance with one example.

FIG. 6 is a block diagram of an example method performed by the controller of FIG. 5.

FIG. 7 is a circuit diagram of a transformer implemented in the CDU of FIG. 1 in accordance with one example.

FIG. 8 is a graphical user interface for the CDU of FIG. 1 in accordance with one example.

FIG. 9 is a flowchart of an example method for operating the CDU of FIG. 1 when temperature sensors associated with a secondary closed loop fail.

FIG. 10 is a flowchart of an example method for controlling the temperature of the second fluid in a secondary closed loop of the CDU of FIG. 1 when a dew point temperature sensor fails.

### DETAILED DESCRIPTION

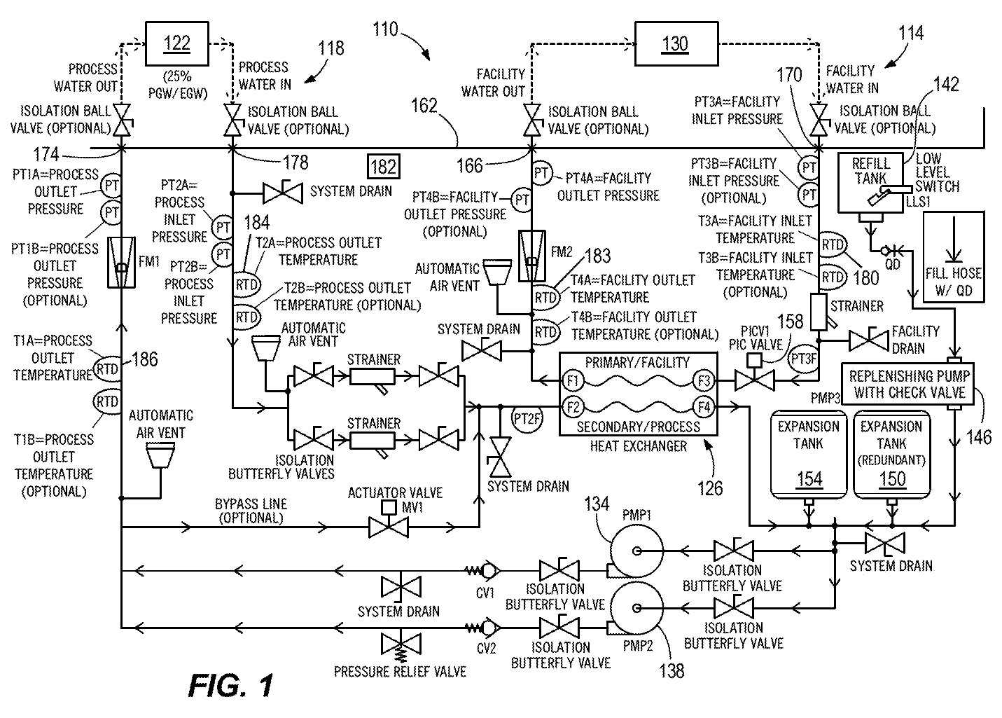

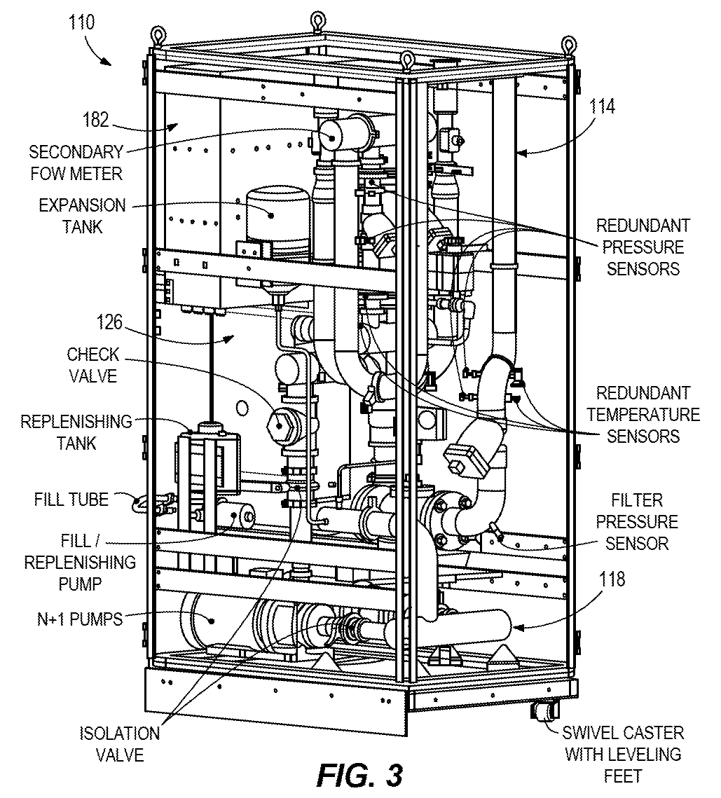

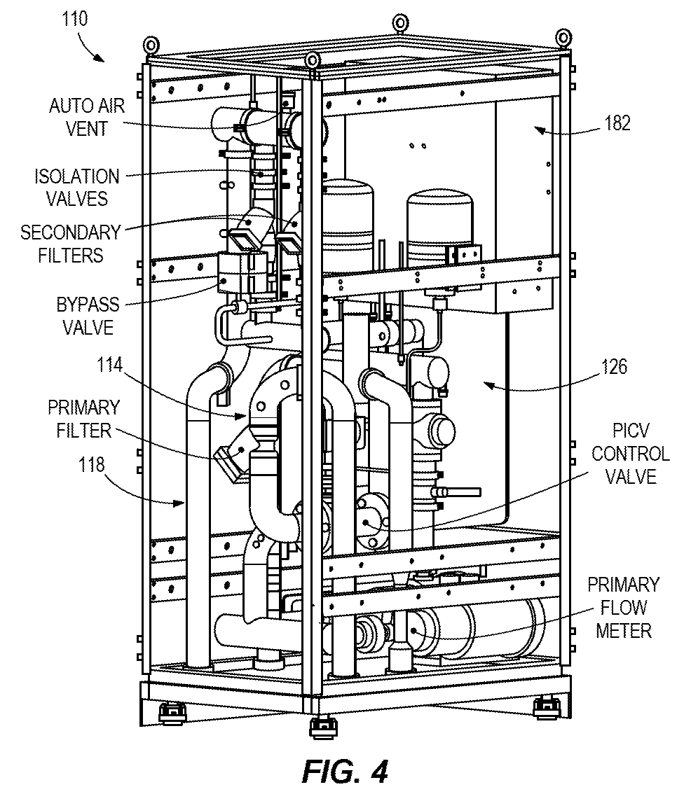

FIGS. 1-4 illustrate an example of a CDU 110. The CDU 110 may be used in any of a variety of settings, including for example in a server, data center, medical, semiconductor, and/or industrial application. The illustrated CDU 110 is an in-row unit, although any of the concepts described herein related to the CDU 110 may alternatively be used with an in-rack unit, or with any other type of cooling distribution unit.

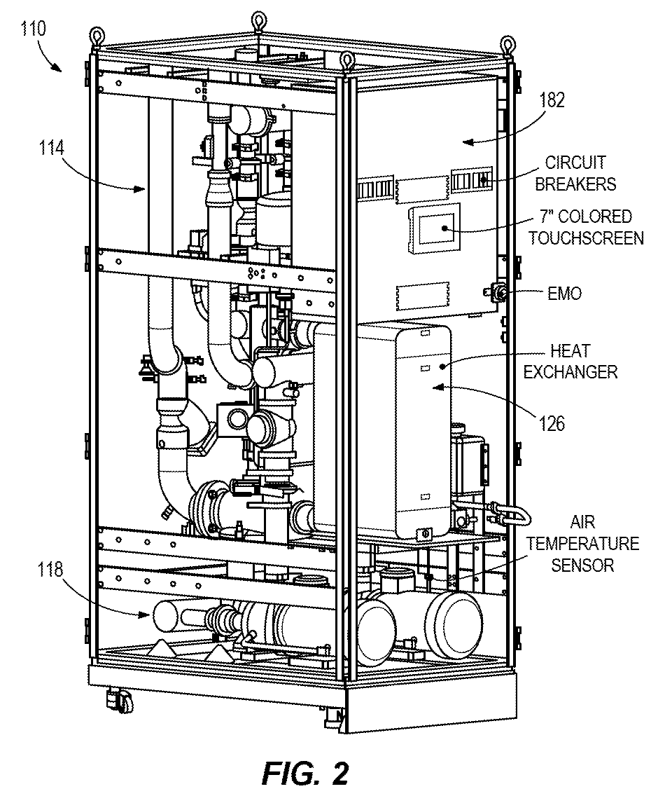

With reference to FIG. 1, the CDU 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. In some examples, at least a portion of the piping for the primary closed loop 114 and/or the secondary closed loop 118 is cylindrical in shape and/or has a circular cross-section. In some examples, at least a portion of the piping for the primary closed loop 114 and/or the secondary closed loop 118 has a linear section and/or a curved section. Other examples include other types of piping, including piping made of other materials (e.g., metal or non-metal), or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of between 100 gallons per minute (GPM) and 200 GPM (e.g., 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the CDU 110. In the illustrated example, the primary closed loop 114 includes a pressure independent control valve 158.

With continued reference to FIG. 1, in the illustrated example, the CDU 110 includes a housing 162 (e.g., an outer housing). The housing 162 may include a steel frame (e.g., with interconnected vertical and/or horizontal frame members), or may be another type of frame, or be formed from different materials. In some examples, the housing 162 includes one or more doors (e.g., pivotally coupled or otherwise coupled to the frame). Other examples may include various other types, sizes, and/or shapes of housing 162 than that illustrated. In the illustrated example the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the CDU 110 additionally includes one or more sensors that measure pressure, temperature, or other aspects of the system. In the illustrated example, the CDU 110 includes a plurality of pressure and temperature sensors (labeled as “PT” and “RTD” in FIG. 1) that are positioned generally at the first outlet 166, the first inlet 170, the second outlet 174, and the second inlet 178. For example, the CDU 110 may include a temperature sensor 180 associated with the first inlet 170 of the primary closed loop 114, a temperature sensor 183 associated with a first outlet 166 of the primary closed loop 114, a temperature sensor 184 associated with the second inlet 178 of the secondary closed loop 118, and a temperature sensor 186 associated with the second outlet 174 of the secondary closed loop 118. As illustrated in FIG. 1, the CDU 110 may include redundant pressure and temperature sensors (e.g., in the event one or more of the sensors fails or provide inaccurate readings).

In some examples, these sensors are coupled (e.g., wired or wirelessly) to a controller 182 (FIGS. 1-4) or other device that receives signals regarding the pressure and temperature of the first fluid and the second fluid. In the illustrated example, the controller 182 is located on and/or within the housing 162, and may include or be connected to an input/output device that displays a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

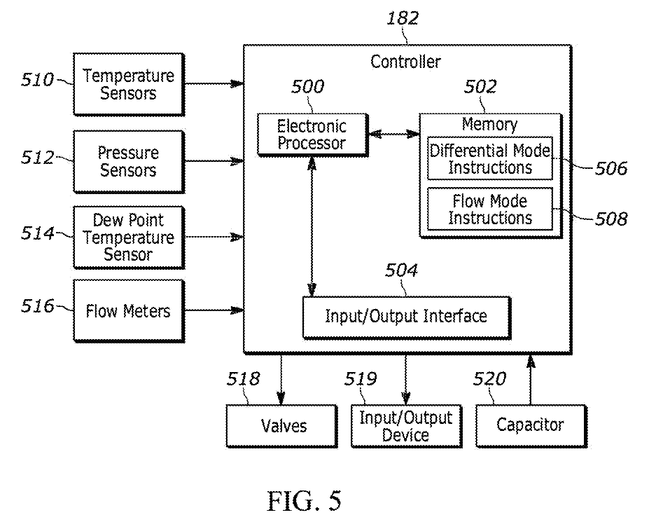

FIG. 5 illustrates a block diagram of the controller 182 of FIGS. 2-4 in accordance with some aspects. The controller 182 includes, among other things, an electronic processor 500, a memory 502, and an input/output (I/O) interface 504. The electronic processor 500, the memory 502, and the I/O interface 504 communicate over one or more control and/or data buses. FIG. 5 illustrates only one example of the controller 182. The controller 182 may include more or fewer components and may perform functions other than those explicitly described herein.

In some examples, the electronic processor 500 is implemented as a microcontroller with a separate memory, such as the memory 502. In other examples, the electronic processor 500 may be implemented as a microcontroller with memory 502 on the same chip. In other examples, the electronic processor 500 may be implemented partially or entirely as, for example, a field-programmable gate array (FPGA), an applications specific integrated circuit (ASIC), and the like and the memory 502 may not be needed or may be modified accordingly.

In the example illustrated, the memory 502 includes non-transitory, computer-readable memory (or medium) that stores instructions that are received and executed by the electronic processor 500 to carry out the functionality of the CDU 110 described herein. The memory 502 may include, for example, a program storage area and a data storage area. The program storage area and the data storage area may include combinations of different types of memory, such as non-volatile read-only memory, non-volatile flash memory and volatile random-access memory. In some implementations, the memory 502 stores instructions that, when executed by the electronic processor 500, cause the electronic processor 500 to perform the functionality described herein.

The controller 182 receives feedback regarding the state of the CDU 110 from temperature sensors 510 (including for example one or more of the temperature sensors 180, 183, 184, and/or 186 described above) , pressure sensors 512, dew point temperature sensors 514, and flow meters 516. In some examples, the temperature sensors 510 are installed near the inlet and outlet locations of the primary closed loop 114 and the secondary closed loop 118 (e.g., the first outlet 166, the first inlet 170, the second outlet 174, and the second inlet 178). The temperature sensors 510 are configured to sense a fluid temperature at their respective locations. The temperature sensors 510 are configured to provide temperature signals to the controller 182 indicative of the fluid temperature.

The pressure sensors 512 are also installed near the inlet and outlet locations of the primary closed loop 114 and the secondary closed loop 118 (e.g., the first outlet 166, the first inlet 170, the second outlet 174, and the second inlet 178). The pressure sensors 512 are configured to measure fluid pressure at their respective locations. The pressure sensors 512 are configured to provide pressure signals to the controller 182 indicative of the fluid pressure.

The dew point temperature sensor 514 is configured to provide a dew signal to the controller 182 indicative of the current dew point temperature and the ambient air temperature. The flow meters 516 are installed on the first outlet 166 and the second outlet 174 lines and are configured to provide a flow signal to the controller 182 indicative of the flow rate of fluid exiting the housing 162 via the first outlet 166 and the second outlet 174.

The controller 182 may be configured to control valves 518 to control the flow of fluid within the CDU 110. For example, a modulating ball valve 518 may be situated at the first outlet 166, the first inlet 170, the second outlet 174 and/or the second inlet 178 to control the flow of fluid into and out of the primary closed loop 114 and/or the secondary closed loop 118. The valves 518 may also include the pressure independent control valve 158.

The controller 182 may be configured to receive input from and/or send output to an input/output device 519. The input/output device 519 may be a microphone, a speaker, a display device (for example, a touch screen), a combination of the foregoing, or the like.

The controller 182 may include and/or be electrically connected to a capacitor 520 for storing energy to provide power to the controller 182.

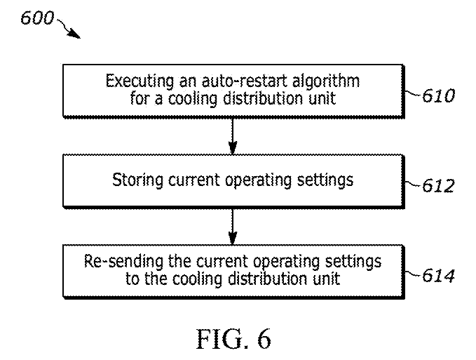

FIG. 6 illustrates a flow diagram for a method 600 of operating the CDU 110. The method 600 may be implemented by the controller 182 using, by way of example, the electronic processor 500.

In the event of a power interruption, at step 610 an auto-restart algorithm may be executed. The auto-restart algorithm begins when a drop in and/or loss of power is detected for a given amount of time. During operation, the method 600 includes at step 612 storing current operating settings in, for example, the memory 502. In one example, operating settings are continuously stored in the memory 502. At step 614, in an event where the drop in and/or loss of power is detected the most recent operating settings are re-sent to the CDU 110 upon power restoration.

The capacitor 520 (FIG. 5) is configured to store enough energy to provide power to run the CDU 110 for the given amount of time. In one example, the CDU 110 can undergo a full second of power loss with no intervention required.

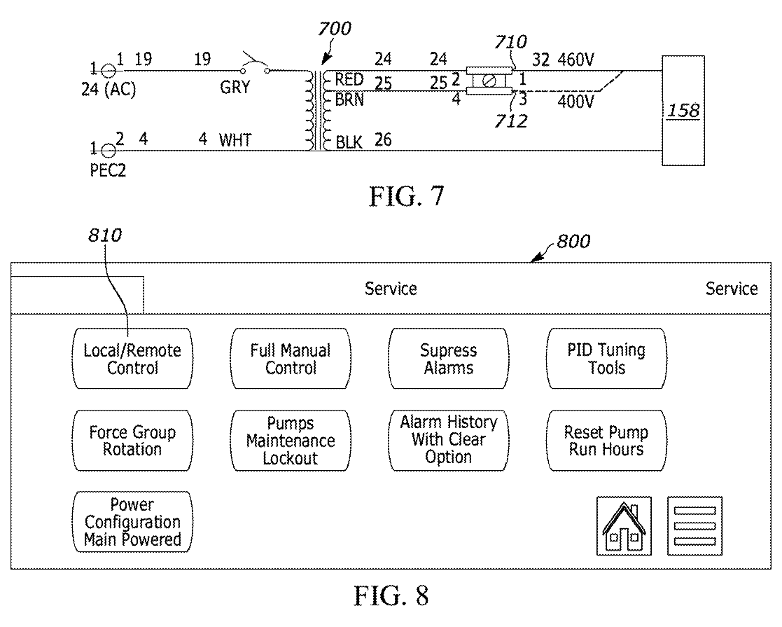

Turning to FIG. 7, in one example the CDU 110 contains a transformer 700 which provides 24 VAC power to the pressure independent control valve 158. For 380V or 400V of incoming power a 400V tap terminal 710 of the transformer 700 is connected to the pressure independent control valve 158. For 460V or 480V incoming power a 460V tap terminal 712 of the transformer 700 is connected to the pressure independent control valve 158.

In one example the auto-restart algorithm is implemented when the CDU 110 is in a remote mode. FIG. 8 illustrates a service menu 800 for the CDU 110 displayed on, by way of example, a user interface displayed on the input/output device 519. A user may select a local/remote control button 810 to toggle between a local control mode and a remote-control mode. In one example when the local/remote control button is selected, a local control is active. An option for setting a local control time-out may be made available. If the local control time-out is activated, after the time-out has passed, the CDU 110 may switch to the remote-control mode. If the local control time-out is not activated, the CDU 110 will remain in the local control mode unless manually set to remote control mode.

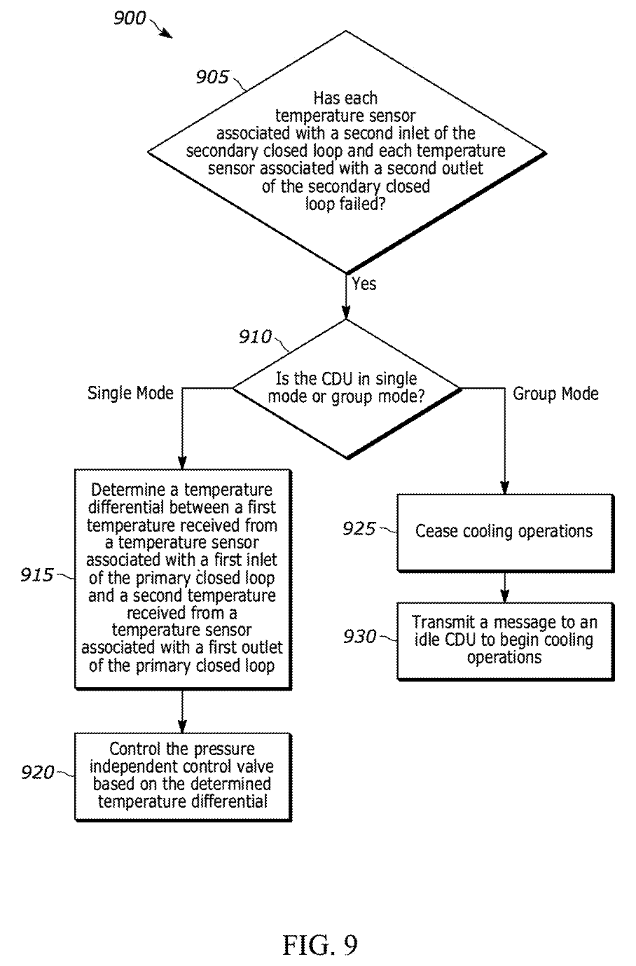

FIG. 9 illustrates an example method 900 for operating a CDU (for example, the CDU 110) when temperature sensors associated with a secondary closed loop fail. In some implementations, the method 900 begins at block 905 when the electronic processor 500 determines whether each temperature sensor associated with the second inlet 178 of the secondary closed loop 118 (for example, the temperature sensor 184 and each of the one or more residual temperature sensors configured to provide a backup temperature measurement when the temperature sensor 184 fails) and each temperature sensor associated with a second outlet 174 of the secondary closed loop 118 (for example, the temperature sensor 186 and each of the one or more residual temperature sensors configured to provide a backup temperature measurement when the temperature sensor 186 fails) has failed. The electronic processor 500 may determine that a temperature sensor has failed when the temperature sensor fails to provide a temperature to the electronic processor or provides an unrealistic or implausible temperature to the electronic processor 500.

In response to determining that each temperature sensor associated with the second inlet 178 of the secondary closed loop 118 and each temperature sensor associated with a second outlet 174 of the secondary closed loop 118 has failed, at block 910, the electronic processor 500 determines whether the CDU 110 is in single mode or group mode. The CDU 110 is in group mode when another currently idle CDU can or is available to perform the functionality currently being performed by the CDU 110. The CDU 110 is in single mode when there is not another currently idle CDU that can perform the functionality currently being performed by the CDU 110.

In some implementations, in response to determining that each temperature sensor associated with the second inlet and each temperature sensor associated with the second outlet have failed, the electronic processor 500 also generates a warning message. For example, the warning message may be a visual or aural message that is output via the input/output device 519.

When the electronic processor 500 determines that the CDU 110 is in single mode, at block 915, the electronic processor 500 determines a temperature differential between a first temperature received from a temperature sensor 180 associated with a first inlet 170 of the primary closed loop 114 and a second temperature received from a temperature sensor 183 associated with a first outlet 166 of the primary closed loop 114.

At block 920, the electronic processor 500 controls the pressure independent control valve 158 based on the determined temperature differential. In one example implementation, the predetermined temperature differential is 10 degrees Celsius. In some implementations, the electronic processor 500 controls the pressure independent control valve 158 based on the determined temperature differential by determining whether the temperature differential is less than, greater than, or equal to a predetermined temperature threshold. In response to determining the temperature differential is less than the predetermined temperature threshold, the electronic processor 500 controls the pressure independent control valve 158 to decrease an opening of the pressure independent control valve 158 to decrease the flow of the first fluid through the heat exchanger 126. In response to determining the temperature differential is greater than the predetermined temperature threshold, the electronic processor 500 controls the pressure independent control valve 158 to increase the opening of the pressure independent control valve 158 to increase the flow of the first fluid through the heat exchanger 126. In response to determining that the temperature differential is greater than the predetermined temperature threshold, the electronic processor 500 maintains (does not increase or decrease) the opening of the pressure independent control valve 158 to maintain the flow of the first fluid through the heat exchanger 126.

In some implementations, when the electronic processor 500 determines that the CDU 110 is in group mode, the electronic processor 500, at block 925, ceases cooling operations and, at block 930, transmits a message to an idle CDU to begin cooling operations. In some implementations, the electronic processor 500, ceases cooling operations of the CDU 110 when the electronic processor 500 receives a message from the idle CDU confirming it has begun cooling operations.

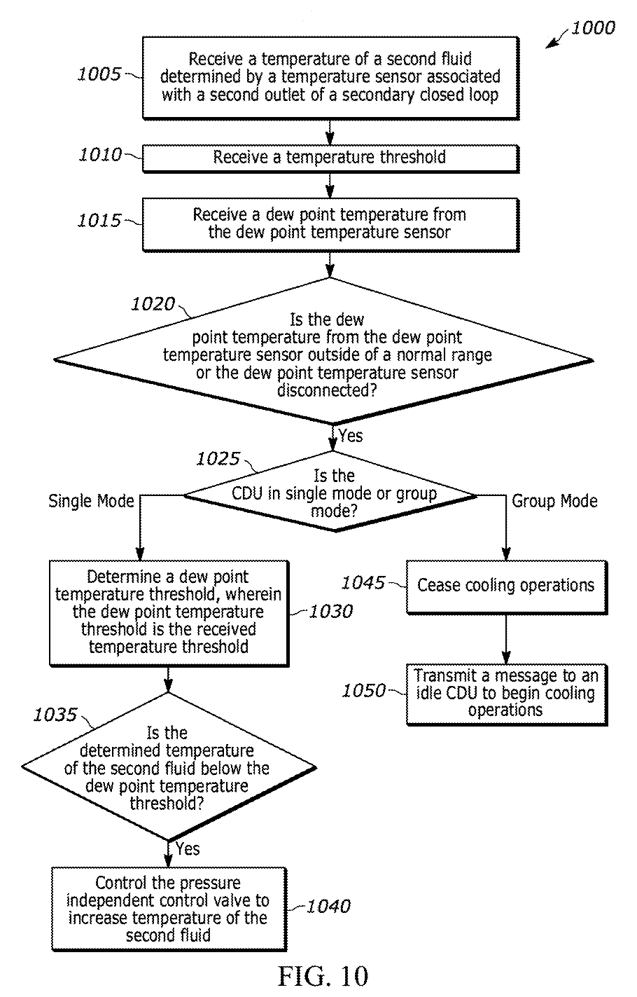

FIG. 10 provides an example flowchart of a method 1000 for controlling the temperature of the second fluid in the secondary closed loop 118 of the CDU 110 when the dew point temperature sensor 514 fails. In some implementations, the method 1000 begins at block 1005 when the electronic processor 500 receives a temperature of a second fluid determined by a temperature sensor associated with a second outlet 174 of a secondary closed loop 118 (for example, the temperature sensor 186 or a residual temperature sensor). At block 1010, the electronic processor 500 may receive a temperature threshold. For example, the electronic processor 500 may receive the temperature threshold from the input/output device 519 when a user or operator enters the temperature threshold via a touchscreen of the input/output device 519.

The electronic processor 500 may, at block 1015, receive a dew point temperature from the dew point temperature sensor 514. In some implementations, at block 1020, the electronic processor 500 determines whether the dew point temperature from the dew point temperature sensor 514 is outside of a normal range or the dew point temperature sensor 514 is disconnected. In some implementations, the normal range is -40°C to 80°C or -40°F to 176°F.

In some implementations, when the dew point temperature from the dew point temperature sensor 514 is inside of a normal range and the dew point temperature sensor 514 is connected the electronic processor 500 determines the dew point temperature threshold to be a predetermined number of degrees above the dew point temperature. The electronic processor 500 also determines whether the determined temperature of the second fluid is below the dew point temperature threshold and, in response to determining the determined temperature of the second fluid is below the dew point temperature threshold, controls the pressure independent control valve 158 to increase temperature of the second fluid before it circulates through and/or across one or more electrical components 122. Increasing the temperature of the second fluid when the temperature of the second fluid, before it circulates through and/or across one or more electrical components 122, drops below the dew point temperature threshold, prevents condensation from forming on the piping of the secondary closed loop 118. Condensation that forms on the piping of the secondary closed loop 118 can potentially damage the electrical components 122.

In some implementations, when the electronic processor 500 determines that the dew point temperature from the dew point temperature sensor 514 is outside of a normal range or the dew point temperature sensor 514 is disconnected, the electronic processor 500, at block 1025, determines whether the CDU 110 is in single mode or group mode. In some implementations, when the electronic processor 500 determines that the dew point temperature from the dew point temperature sensor 514 is outside of a normal range or the dew point temperature sensor 514 is disconnected, the electronic processor 500, the electronic processor 500 generates a warning. For example, the warning may be a visual or aural message that is output via the input/output device 519.

When the electronic processor 500 determines that the CDU 110 is in single mode, the electronic processor 500 determines, at block 1030, that dew point temperature threshold to be the received temperature threshold (the temperature threshold received at block 1010). In some implementations, at block 1035, the electronic processor 500 determines whether the determined temperature of the second fluid is below the dew point temperature threshold. When the determined temperature of the second fluid is below the dew point temperature threshold, the electronic processor 500 may, at block 1040, control the pressure independent control valve 158 to increase temperature of the second fluid before it circulates through and/or across one or more electrical components 122.

In some implementations, when the electronic processor 500 determines that the CDU 110 is in group mode, the electronic processor 500, at block 1045, ceases cooling operations and, at block 1050, transmits a message to an idle CDU to begin cooling operations. In some implementations, the electronic processor 500, ceases cooling operations of the CDU 110 when the electronic processor 500 receives a message from the idle CDU confirming it has begun cooling operations.

In the illustrated example, the CDU 110 has an overall dimension of 31.5” by 47.4” by 84.5”, and an overall weight of approximately 1400 pounds. Other examples may include various different sizes and weights, including sizes smaller and larger than that illustrated, and weights smaller or greater than that illustrated. Additionally, in the illustrated example, the CDU 110 may provide a cooling capacity of 550kW (at 4ºC approach temperature difference) and 1100kW (at 8ºC approach temperature difference). Other examples may include other values and ranges of values of cooling capacity, including a cooling capacity smaller or greater than that illustrated.

The benefits, advantages, solutions to problems, and any element(s) that may cause any benefit, advantage, or solution to occur or become more pronounced are not to be construed as a critical, required, or essential features or elements of any or all the claims. The disclosure is defined solely by the appended claims including any amendments made during the pendency of this application and all equivalents of those claims as issued.

In this document relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus.

It should also be noted that a plurality of hardware and software-based devices, as well as a plurality of different structural components may be utilized in various implementations. Aspects, features, and instances may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one instance, the electronic based aspects of the disclosure may be implemented in software (for example, stored on non-transitory computer-readable medium) executable by one or more processors. As a consequence, it should be noted that a plurality of hardware and software-based devices, as well as a plurality of different structural components may be utilized to implement the disclosure. For example, “control units” and “controllers” described in the specification can include one or more electronic processors, one or more memories including a non-transitory computer-readable medium, one or more input/output interfaces, and various connections (for example, a system bus) connecting the components.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

It should also be understood that although certain drawings illustrate hardware and software located within particular devices, these depictions are for illustrative purposes only. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all the multiple determinations collectively. To reiterate, those electronic processors and processing may be distributed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

In the foregoing specification, specific examples have been described. However, one of ordinary skill in the art appreciates that various modifications and changes may be made without departing from the scope of the disclosure as set forth in the claims below. Accordingly, the specification and figures are to be regarded in an illustrative rather than a restrictive sense, and all such modifications are intended to be included within the scope of present teachings.

What is claimed is:

1. A cooling distribution unit (CDU) comprising:
a primary closed loop, wherein a first fluid circulates through the primary closed loop;
a secondary closed loop, wherein a second fluid circulates through the secondary closed loop;
a pressure independent control valve;
a first temperature sensor associated with an inlet of the primary closed loop;
a second temperature sensor associated with an outlet of the primary closed loop;
a third temperature sensor associated with an inlet of the secondary closed loop;
a fourth temperature sensor associate with an outlet of the secondary closed loop; and
an electronic processor, the electronic processor configured to:
determine whether both the third temperature sensor and the fourth temperature sensor have failed; and
in response to determining that both the third temperature sensor and the fourth temperature sensor have failed,
determine whether the CDU is in a single mode or a group mode; and in response to determining the CDU is in the single mode,
determine a temperature differential between a first temperature received from the first temperature sensor and a second temperature received from the second temperature sensor; and
control the pressure independent control valve based on the determined temperature differential.

2. The CDU according to claim 1, wherein the electronic processor is configured to control the pressure independent control valve based on the determined temperature differential by determining whether the temperature differential is less than, greater than, or equal to a predetermined temperature threshold.

3. The CDU according to claim 2, wherein in response to determining the temperature differential is less than the predetermined temperature threshold, the electronic processor is configured to control the pressure independent control valve to decrease an opening of the pressure independent control valve.

4. The CDU according to claim 2, wherein in response to determining the temperature differential is greater than the predetermined temperature threshold, the electronic processor is configured to control the pressure independent control valve to increase an opening of the pressure independent control valve.

5. The CDU according to claim 2, wherein in response to determining that the temperature differential is greater than the predetermined temperature threshold, the electronic processor is configured to maintain an opening of the pressure independent control valve.

6. The CDU according to claim 2, wherein the predetermined temperature differential is 10 degrees Celsius.

7. The CDU according to claim 1, wherein the electronic processor is further configured to:
in response to determining the CDU is in the group mode,
cease cooling operations; and
transmit a message to an idle CDU to begin cooling operations.

8. The CDU according to claim 1, wherein the electronic processor is further configured to:
in response to determining that both the third temperature sensor and the fourth temperature sensor have failed, generate a warning message.

9. The CDU according to claim 1, further comprising a fifth temperature sensor associated with the inlet of the secondary closed loop and a sixth temperature sensor associated with the outlet of the secondary closed loop, wherein the fifth temperature sensor is a residual temperature sensor configured to provide a backup temperature measurement if the third temperature sensor fails, and wherein the sixth temperature sensor is a residual temperature sensor configured to provide a backup temperature measurement if the fourth temperature sensor fails.

10. The CDU according to claim 9, wherein the electronic processor is configured to determine whether each of the third temperature sensor, the fourth temperature sensor, the fifth temperature sensor, and the sixth temperature sensor have failed.

11. The CDU according to claim 10, wherein in response to determining that each of the third temperature sensor, the fourth temperature sensor, the fifth temperature sensor, and the sixth temperature sensor have failed, the electronic processor is configured to
determine whether the CDU is in the single mode or the group mode; and
in response to determining that the CDU is in the single mode, determine the temperature differential between the first temperature received from the first temperature sensor and the second temperature received from the second temperature sensor, and control the pressure independent control valve based on the determined temperature differential.

12. A cooling distribution unit (CDU) comprising:
a secondary closed loop, wherein a second fluid circulates through the secondary closed loop;
a dew point temperature sensor;
a pressure independent control valve; and
an electronic processor, the electronic processor configured to:
receive a temperature of the second fluid determined by a temperature sensor associated with an outlet of the secondary closed loop;
receive a temperature threshold;
receive a dew point temperature from the dew point temperature sensor;
determine whether the dew point temperature is outside a normal range;
determine whether the dew point temperature sensor is disconnected; and
in response to determining the dew point temperature from the dew point temperature sensor is outside of the normal range or the dew point temperature sensor is disconnected,
determine whether the CDU is in a single mode or a group mode; and
in response to determining the CDU is in single mode,
determine a dew point temperature threshold, wherein the dew point temperature threshold is the received temperature threshold;
determine whether the determined temperature of the second fluid is below the dew point temperature threshold; and
in response to determining the determined temperature of the second fluid is below the temperature threshold, control the pressure independent control valve to increase temperature of the second fluid.

13. The CDU according to claim 12, wherein the normal range is between 40 degrees Celsius and 80 degrees Celsius.

14. The CDU according to claim 12, wherein the electronic processor is further configured to:
in response to determining the dew point temperature is within the normal range and the dew point temperature sensor is connected, determine the dew point temperature threshold, wherein the dew point temperature threshold is a predetermined number of degrees above the dew point temperature.

15. The CDU according to claim 14, wherein the electronic processor is configured to
determine whether the determined temperature of the second fluid is below the dew point temperature threshold.

16. The CDU according to claim 15, wherein the electronic processor is further configured to:
in response to determining the determined temperature of the second fluid is below the dew point temperature threshold, increase temperature of the second fluid.

17. The CDU according to claim 12, wherein the electronic processor is further configured to:
in response to determining the CDU is in the group mode,
cease cooling operations; and
transmit a message to an idle CDU to begin cooling operations.

18. The CDU according to claim 12, wherein the electronic processor is further configured to:
in response to determining the dew point temperature from the dew point temperature sensor is outside of the normal range or the dew point temperature sensor is disconnected, generate a warning message.

19. The CDU according to claim 12, further comprising a primary closed loop, wherein a first fluid circulates through the primary closed loop.

20. The CDU according to claim 19, further comprising a heat exchanger configured to pass heat from the second fluid in the secondary closed loop to the first fluid in the primary closed loop.
